(19) United States
(12) Patent Application Publication
(10) Pub. No.: US 2023/0064237 A1
(43) Pub. Date: Mar. 2, 2023

(54) IMPRINT METHOD, IMPRINT APPARATUS, ARTICLE MANUFACTURING METHOD, MODEL, MODEL GENERATION METHOD, AND STORAGE MEDIUM

(71) Applicant: CANON KABUSHIKI KAISHA, Tokyo (JP)

(72) Inventors: Shinichiro Koga, Tochigi (JP); Kento Watanabe, Tochigi (JP)

(21) Appl. No.: 17/884,799

(22) Filed: Aug. 10, 2022

(30) Foreign Application Priority Data
Aug. 24, 2021 (JP) 2021-136653

(51) Int. Cl. B29C 59/00; B29C 59/02

(52) U.S. Cl. CPC B29C 59/002; B29C 59/026; B29C 2037/903

(57) ABSTRACT

The present invention provides an imprint method of performing, for each of a plurality of shot regions on a substrate, a process of forming a pattern of an imprint material on the substrate using a mold, comprising: obtaining a model configured to receive condition information representing a condition of the process and output an extrusion state of the imprint material from a shot region; estimating the extrusion state of the imprint material from at least one first shot region that has already undergone the process, by the model, based on the condition information obtained in the process of the first shot region; and determining, based on the estimated extrusion state in the first shot region, whether to execute the process for a second shot region scheduled to undergo the process next to the first shot region.

### BACKGROUND OF THE INVENTION

### Field of the Invention

The present invention relates to an imprint method, an imprint apparatus, an article manufacturing method, a model, a model generation method, and a storage medium.

### Description of the Related Art

As a technique of forming a fine pattern on a substrate, a lithography technique using an exposure apparatus configured to transfer the pattern of an original to a substrate via a projection optical system is known. In recent years, an imprint technique of molding an imprint material on a substrate using a mold and transferring a fine pattern formed in the mold to a substrate has also received a great deal of attention as one of lithography techniques (see Japanese Patent Laid-Open No. 2019-80047). In the imprint technique, for example, processing (imprint process) of bringing an imprint material supplied onto a shot region of a substrate into contact with a mold, curing the imprint material by irradiating it with light in this state, and after that, separating the mold from the cured imprint material is performed. Accordingly, a pattern made of the cured product of the imprint material can be formed on the substrate.

In the imprint process, in the step of bringing the imprint material supplied onto the shot region of the substrate into contact with the mold, the imprint material may be extruded to the outside of the shot region and cured in that state. In this case, in the imprint process of the subsequent shot region to which the imprint material is extruded, the extruded imprint material and the mold may come into contact with each other, resulting in difficulty in accurately forming the pattern on the shot region. Also, if the extruded imprint material and the mold come into contact, the pattern of the mold may break. For this reason, it is preferable to obtain the extrusion state of the imprint material from the shot region that has already undergone the imprint process and determine, in accordance with the obtained extrusion state, whether to perform the imprint process of the subsequent shot region.

As one of methods of obtaining (detecting) the extrusion state of the imprint material from the shot region of the substrate, a method using a camera is present. However, the portion where the extrusion of the imprint material occurs is a very small region. Hence, in this method, each of a plurality of partial regions of the shot region needs to be captured using a camera with a high magnification (high resolution) and analyzed, and this may be disadvantageous in terms of apparatus cost and throughput.

### SUMMARY OF THE INVENTION

The present invention provides, for example, a technique advantageous in easily obtaining the extrusion state of an imprint material from a shot region of a substrate.

According to one aspect of the present invention, there is provided an imprint method of performing, for each of a plurality of shot regions on a substrate, a process of forming a pattern of an imprint material on the substrate using a mold, comprising: obtaining a model configured to receive condition information representing a condition of the process and output an extrusion state of the imprint material from a shot region; estimating the extrusion state of the imprint material from at least one first shot region that has already undergone the process among the plurality of shot regions, by the model, based on the condition information obtained in the process of the first shot region; and determining, based on the extrusion state in the first shot region estimated in the estimating, whether to execute the process for a second shot region scheduled to undergo the process next to the first shot region among the plurality of shot regions.

Further features of the present invention will become apparent from the following description of exemplary embodiments with reference to the attached drawings.

### BRIEF DESCRIPTION OF THE DRAWINGS

FIG. 1 is a flowchart showing an operation (imprint process) of an imprint apparatus according to an embodiment of the present invention;

FIGS. 2A and 2B are schematic views showing an example of the configuration of the imprint apparatus according to an embodiment of the present invention;

FIG. 3 is a view showing an example of the configuration of an article manufacturing system;

FIG. 4 is a view showing an example of the arrangement of a plurality of shot regions on a substrate;

FIGS. 5A to 5C are views for explaining extrusion of the imprint material from a shot region;

FIG. 6 is a flowchart showing a determination step (step S102);

FIG. 7 is a flowchart showing an estimation step (step S108);

FIGS. 8A and 8B are views showing the outline of a model for estimating the extrusion state of the imprint material;

FIG. 9 is a flowchart showing a model generation method; and

FIGS. 10A to 10F are views showing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

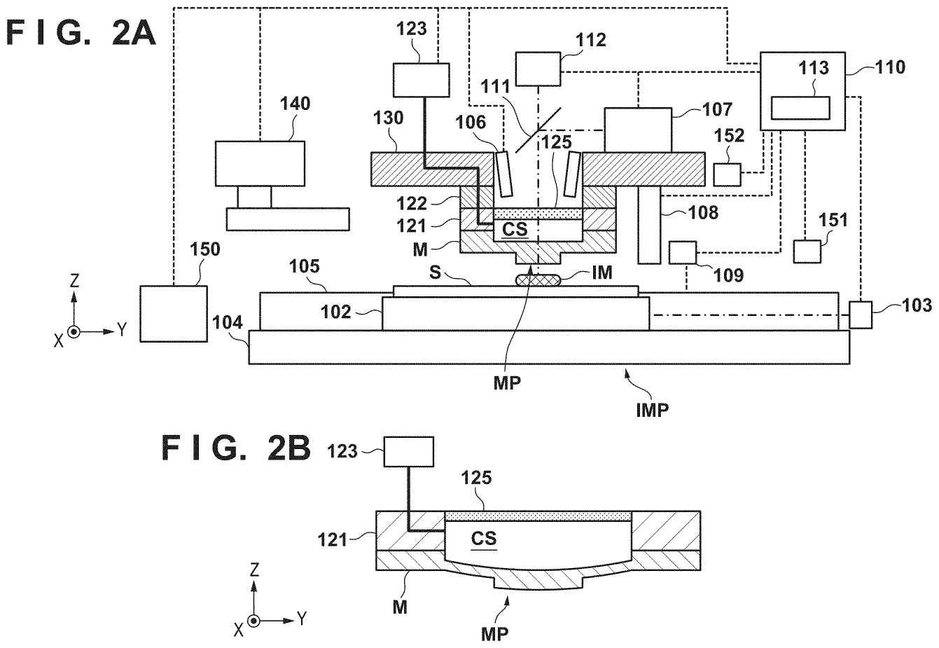

An imprint apparatus IMP according to an embodiment of the present invention will be described. FIG. 2A is a schematic view showing an example of the configuration of the imprint apparatus IMP according to this embodiment. The imprint apparatus IMP is an apparatus that brings a mold into contact with an imprint material supplied onto a substrate and gives energy for curing to the imprint material, thereby forming the pattern of a cured product to which the uneven pattern of the mold is transferred. For example, the imprint apparatus IMP supplies a liquid imprint material IM as a plurality of droplets onto a substrate S, and cures the imprint material in a state in which a mold M with an uneven pattern is in contact with the imprint material IM on the substrate S. Then, the imprint apparatus increases the interval between the mold M and the substrate S to separate (mold separation) the mold M from the cured imprint material IM, thereby transferring the pattern of the mold M to the imprint material IM on the substrate S. The series of processes is called an “imprint process”, and is performed for each of a plurality of shot regions on the substrate S.

As the imprint material IM, a curable composition (to be also referred to as a resin in an uncured state) to be cured by receiving curing energy is used. As the curing energy, an electromagnetic wave or heat can be used. The electromagnetic wave can be, for example, light selected from the wavelength range of 10 nm (inclusive) to 1 mm (inclusive), for example, infrared rays, visible light, or ultraviolet light. The curable composition can be a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material IM can be arranged on the substrate in the form of droplets or in the form of an island or film formed by connecting a plurality of droplets. The viscosity (the viscosity at 25° C.) of the imprint material IM can be, for example, from 1 mPa·s (inclusive) to 100 mPa·s (inclusive).

The mold M is normally made of a material such as quartz that can transmit UV light. In a partial region MP (mesa region) protruding toward the substrate side on the substrate side surface, an uneven pattern to be transferred to the imprint material IM on the substrate S is formed. The partial region MP (mesa region) will sometimes be expressed as a pattern region MP hereinafter. As the substrate S, glass, ceramic, a metal, a semiconductor, a resin, or the like is used, and a member made of a material different from that of the substrate may be formed on the surface of the substrate, as needed. More specifically, the substrate S is a silicon wafer, a semiconductor compound wafer, silica glass, or the like. An adhesion layer may be provided to improve the adhesion between the imprint material and the substrate, as needed, before the application of the imprint material IM.

In the specification and the accompanying drawings, directions will be indicated on an XYZ coordinate system in which directions parallel to the surface of the substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the ex-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of the substrate and the mold.

The imprint apparatus IMP can include a substrate holding unit 102 that holds the substrate S, a substrate driving mechanism 105 that drives the substrate S by driving the substrate holding unit 102, a base 104 that supports the substrate holding unit 102, and a position measuring unit 103 that measures the position of the substrate holding unit 102. The substrate driving mechanism 105 can include, for example, a motor such as a linear motor. The imprint apparatus IMP can include a sensor 151 that detects a driving force (alignment load) necessary for the substrate driving mechanism 105 to drive the substrate S and the mold M relatively in alignment between the mold M and the substrate S. The driving force in alignment that is performed in a state in which the imprint material IM on the substrate S and the pattern region MP of the mold M are in contact with each other corresponds to a shearing force that acts between the substrate S and the mold M. The shearing force is mainly a force that acts on the substrate S and the mold M in a plane direction (X and Y directions). The driving force in alignment has, for example, correlation with the magnitude of a current supplied to the motor of the substrate driving mechanism 105 in alignment, and the sensor 151 can detect the driving force based on the magnitude of the current. The sensor 151 is an example of a sensor configured to measure the influence (shearing force) received by the substrate S or the mold M during pattern formation. Note that a driving request (command value) output from a control unit 110 (to be described later) to the substrate driving mechanism 105 will sometimes be referred to as a stage control value.

The imprint apparatus IMP can include a mold holding unit 121 that holds the mold M, a mold driving mechanism 122 that drives the mold M by driving the mold holding unit 121, and a support structure 130 that supports the mold driving mechanism 122. The mold driving mechanism 122 can include, for example, a motor such as a voice coil motor. The imprint apparatus IMP can include a sensor 152 that detects a mold separation force (separation load) and/or a pressing force. The mold separation force is a force necessary for separating (releasing) the cured product of the imprint material IM on the substrate S and the mold M from each other. The pressing force is a force for pressing the mold M against the imprint material IM on the substrate S to make the mold M contact the imprint material IM on the substrate S. The mold separation force and the pressing force are forces that mainly act in a direction (Z direction) perpendicular to the plane direction of the substrate S and the mold M. The mold separation force and the pressing force are, for example, correlated to the magnitude of a current supplied to the motor of the mold driving mechanism 122, and the sensor 152 can detect the mold separation force and the pressing force based on the magnitude of the current. The sensor 152 is an example of a sensor for measuring the influence (mold separation force and/or pressing force) received by the mold M during the pattern formation. Note that a driving request (command value) output from the control unit 110 (to be described later) to the mold driving mechanism 122 will also be sometimes referred to as a stage control value.

The substrate driving mechanism 105 and the mold driving mechanism 122 form a driving mechanism for adjusting a relative position and a relative posture between the substrate S and the mold M. The adjustment of the relative position between the substrate S and the mold M includes driving to bring the mold into contact with the imprint material on the substrate S and separate the mold from the cured imprint material (a pattern made of the cured product). The substrate driving mechanism 105 can be configured to drive the substrate S for a plurality of axes (for example, three axes including the X-axis, the Y-axis, and the θZ-axis, and preferably, six axes including the X-axis, the Y-axis, the Z-axis, the X-axis, the θY-axis, and the θZ-axis). The mold driving mechanism 122 can be configured to drive the mold M for a plurality of axes (for example, three axes including the Z-axis, the θX-axis, and the θY-axis, and preferably, six axes including the X-axis, the Y-axis, the Z-axis, the ex-axis, the θX-axis, and the θZ-axis).

Also, the mold holding unit 121 can include a window member 125 configured to form a substantially sealed pressure control space CS on the side of the back surface of the mold M (the surface opposite to the surface where the pattern region MP is provided). In the imprint apparatus IMP, the pressure (to be referred to as a cavity pressure hereinafter) in the pressure control space CS is controlled by a deformation mechanism 123, thereby deforming the pattern region MP of the mold M in a convex shape toward the substrate S, as schematically shown in FIG. 2B. For example, when the mold M is deformed in a convex shape in a contact step of bringing the mold M into contact with the imprint material IM on the substrate S, the mold M (pattern region MP) can gradually be brought into contact with the imprint material IM, thereby reducing confinement of a gas in the concave portions of the pattern of the mold M. That is, unfilling of the imprint material IM into the pattern of the mold M can be reduced. Also, when the mold M is deformed in a convex shape in the mold separation step of separating the cured product of the imprint material IM on the substrate S from the mold M, breakage of the pattern made of the cured product of the imprint material IM formed on the substrate S can be reduced. Note that the cavity pressure may be understood as a force (deformation force) applied to the mold M to deform the mold M in a convex shape.

The imprint apparatus IMP can include a mold conveyance mechanism 140 that conveys the mold M, and a mold cleaner 150. The mold conveyance mechanism 140 can be configured to, for example, convey the mold M to the mold holding unit 121 and convey the mold M from the mold holding unit 121 to a mold stocker (not shown) or the mold cleaner 150. The mold cleaner 150 cleans the mold M using UV light, a chemical solution, and the like.

The imprint apparatus IMP can include an alignment measuring device 106, a wide-angle alignment measuring device 109, a curing unit 107, an image capturing unit 112, and an optical member 111 (beam splitter). The alignment measuring device 106 illuminates an alignment mask on the substrate S and an alignment mark on the mold M and captures these alignment marks, thereby measuring the relative position between the marks (that is, the relative position between the mold M and the substrate S). The alignment measuring device 106 is positioned by a driving mechanism (not shown) in accordance with the positions of alignment marks to be observed. The wide-angle alignment measuring device 109 is a measuring device having a visual field wider than the alignment measuring device 106, and illuminates the alignment mark of the substrate S and captures the alignment mark, thereby measuring the position of the substrate S. When the position of the substrate S is measured by the wide-angle alignment measuring device 109, the alignment mark of the substrate S can be arranged in the visual field of the alignment measuring device 106. The curing unit 107 irradiates the imprint material IM with energy (for example, light such as UV light) for curing the imprint material IM via the optical member 111, thereby curing the imprint material IM. The image capturing unit 112 captures the substrate S, the mold M, and the imprint material IM via the optical member 111 and the window member 125. An image captured by the image capturing unit 112 will sometimes be referred to as a spread image hereinafter.

The imprint apparatus IMP can include a dispenser 108 that arranges (supplies) the imprint material IM on the substrate S. The dispenser 108, for example, discharges the imprint material IM as a plurality of droplets such that the imprint material IM is arranged on the substrate S in accordance with a drop recipe representing the arrangement of the imprint material IM.

The imprint apparatus IMP can include the control unit 110 that controls the substrate driving mechanism 105, the mold driving mechanism 122, the deformation mechanism 123, and mold conveyance mechanism 140, the mold cleaner 150, the alignment measuring device 106, the curing unit 107, the image capturing unit 112, the dispenser 108, and the like. The control unit 110 can be formed by an information processing apparatus (computer) including a processor such as a CPU and a memory. For example, the control unit 110 may be formed by an PLD (short for Programmable Logic Device) such as an FPGA (short for Field Programmable Gate Array), including a calculation mechanism 113 that is an information processing apparatus, an ASIC (short for Application Specific Integrated Circuit), a general-purpose computer incorporating a program, or a combination of some or all of these.

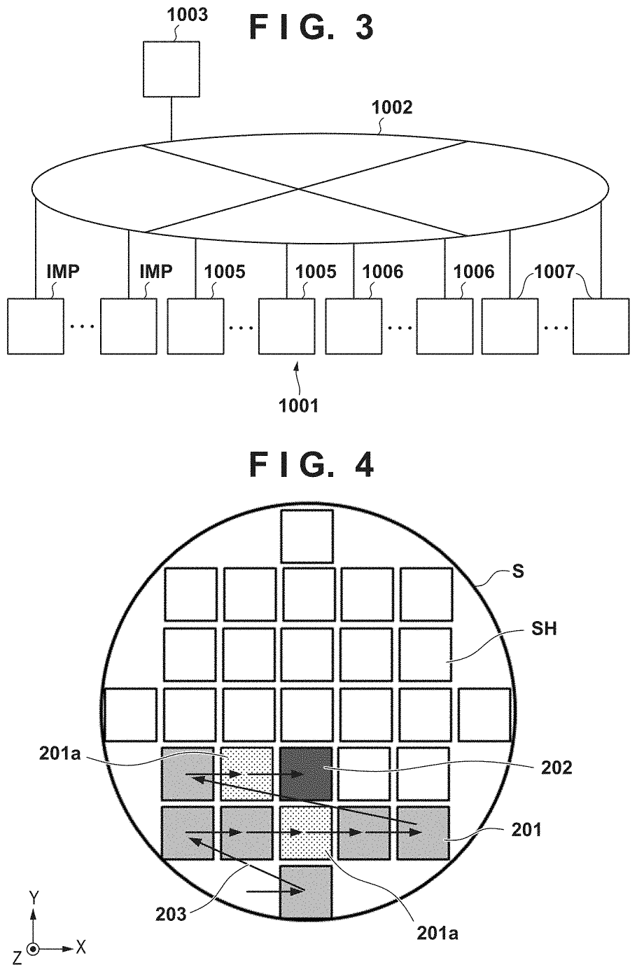

FIG. 3 shows an example of the configuration of an article manufacturing system 1001 configured to manufacture an article such as a semiconductor device. The article manufacturing system 1001 can include, for example, one or a plurality of lithography apparatuses (the imprint apparatus IMP and/or an exposure apparatus). FIG. 3 shows the imprint apparatus IMP as a lithography apparatus. In addition, the article manufacturing system 1001 can include one or a plurality of inspection apparatuses 1005 (for example, an overlay inspection apparatus, a DC inspection apparatus, a defect inspection apparatus, and an electric characteristic inspection apparatus), and one or a plurality of post-processing apparatuses 1006 (an etching apparatus and a deposition apparatus). Furthermore, the article manufacturing system 1001 can include a model generation apparatus 1007 (machine learning unit) that generates a model (learned model) used to estimate extrusion of the imprint material IM from a shot region based on condition information representing the condition of the imprint process. These apparatuses are connected, via a network 1002, to a control apparatus 1003 that is an external apparatus different from the imprint apparatus IMP, and can be controlled by the control apparatus 1003. Note that the condition information may be understood as information representing the condition (operation or state) of the imprint apparatus IMP during the imprint process and is sometimes called device data.

Here, the model generation apparatus 1007 can be formed by an information processing apparatus (computer) including a processor such as a CPU and a memory, like the control unit 110 of the imprint apparatus IMP. For example, the model generation apparatus 1007 may be formed by an PLD (short for Programmable Logic Device) such as an FPGA (short for Field Programmable Gate Array), an ASIC (short for Application Specific Integrated Circuit), a general-purpose computer incorporating a program, or a combination of some or all of these. In addition, the model generation apparatus 1007 may be incorporated in the control unit 110 of the imprint apparatus IMP, the control apparatus 1003, or the inspection apparatus 1005. Note that the system including the lithography apparatus such as the imprint apparatus IMP or the exposure apparatus, the control apparatus 1003, the inspection apparatus 1005, and the model generation apparatus 1007 may be understood as a lithography system.

[Imprint Process]

An imprint process (imprint method) performed by the imprint apparatus IMP according to this embodiment will be described next. In the imprint process, generally, in the contact step of bringing the mold M into contact with the imprint material IM supplied onto a shot region of the substrate S, the imprint material IM may be extruded to the outside of the shot region and cured in that state. In this case, in the imprint process of the subsequent shot region to which the imprint material IM is extruded, the extruded imprint material IM and the mold M may come into contact with each other, resulting in difficulty in accurately forming the pattern on the shot region. Also, if the extruded imprint material IM and the mold M come into contact, the pattern of the mold M may break. Note that the extrusion of the imprint material IM is sometimes called ooze of the imprint material IM.

FIG. 4 shows an example of the arrangement of a plurality of shot regions SH on the substrate S. The imprint apparatus IMP can employ a step-and-repeat method in which the plurality of shot regions SH are set on the substrate S, and the imprint process is sequentially performed for each of the plurality of shot regions SH. In the example shown in FIG. 4, as indicated by an arrow 203, the imprint process can be executed sequentially for each of the plurality of shot regions SH. Here, when performing the imprint process of a target shot region 202 in the plurality of shot regions SH, which is scheduled to undergo the imprint process, it may be affected by extrusion of the imprint material IM from a processed shot region 201 that has already undergone the imprint process. For example, assume a case where extrusion of the imprint material IM occurs from a processed shot region 201a located adjacent to the target shot region 202. In this case, in the imprint process of the target shot region 202, the imprint material IM extruded from the processed shot region 201a and the mold M may come into contact with each other, resulting in difficulty in accurately forming the pattern on the target shot region 202. Also, even if extrusion of the imprint material IM occurs on the processed shot region 201 other than that adjacent to the target shot region 202, the extruded imprint material IM may adhere to the mold M and affect the imprint process of the target shot region 202.

In a conventional imprint apparatus, the extrusion state of an imprint material from a processed shot region is detected using a camera such as the wide-angle alignment measuring device 109 or the image capturing unit 112, and it is determined, in accordance with the detection result, whether to perform the imprint process of the subsequent shot region. However, the portion where the extrusion of the imprint material occurs is a very small region. Hence, in this method, each of a plurality of partial regions of the shot region needs to be captured using a camera with a high magnification (high resolution) and analyzed, and this may be disadvantageous in terms of apparatus cost and throughput.

Hence, the imprint apparatus IMP according to this embodiment uses a model (learned model) configured to receive condition information representing the condition of the imprint process and output the extrusion state of the imprint material IM from a shot region. More specifically, the extrusion state in at least one first shot region (processed shot region) that has already undergone the imprint process is estimated by the model based on the condition information obtained by the imprint process of the first shot region. Based on the extrusion state of the imprint material IM estimated for the first shot region, it is determined whether to execute the imprint process for a second shot region (target shot region) that is scheduled to undergo the imprint process next to the first shot region. When the extrusion state of the imprint material IM is estimated using the model, it is unnecessary to provide a camera with a high magnification in the imprint apparatus IMP or capture each of the plurality of partial regions of the shot region by the camera and analyze. Hence, it can be advantageous in terms of apparatus cost and throughput. Note that the second shot region can be understood not only as the target shot region that should undergo the imprint process but also as each of shot regions (unprocessed shot regions) that are scheduled to undergo the imprint process after the first shot region (processed shot region).

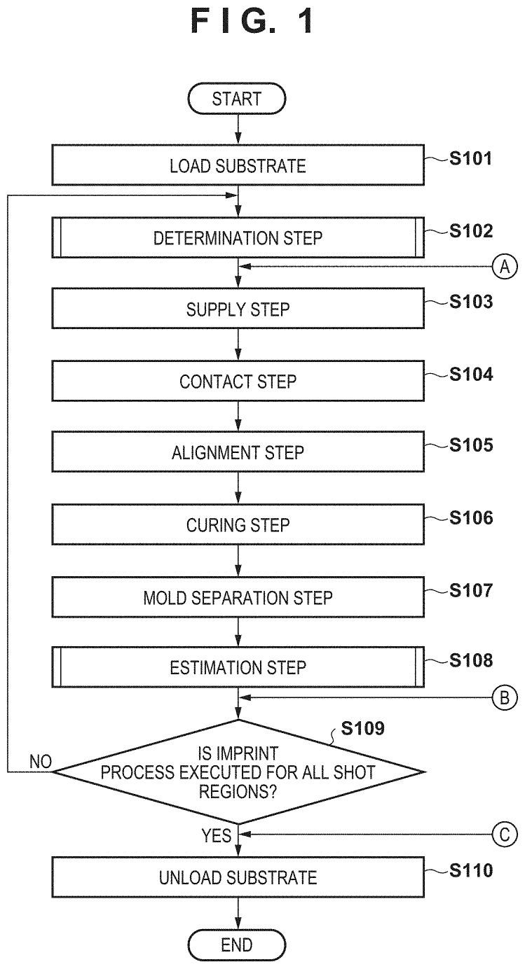

FIG. 1 is a flowchart showing an operation (imprint process) of the imprint apparatus IMP according to this embodiment. Steps shown in the flowchart of FIG. 1 can be performed by the control unit 110. When processing a lot formed by a plurality of substrates, the flowchart shown in FIG. 1 is executed for each of the plurality of substrates included in the lot.

In step S101, the control unit 110 conveys, by a substrate conveyance mechanism (not shown), the substrate S from a conveyance source (for example, a relay unit to a preprocessing apparatus) onto the substrate holding unit 102. Also, in step S101, the control unit 110 may measure the position, on the substrate holding unit 102, of the substrate S conveyed onto the substrate holding unit 102 by observing a mark on the substrate S by the wide-angle alignment measuring device 109. This allows the control unit 110 to position the substrate S by the substrate driving mechanism 105 based on the position of the substrate S measured using the wide-angle alignment measuring device 109.

In step S102, based on the estimation result of the extrusion state of the imprint material IM on the processed shot region of the plurality of shot regions on the substrate S, the control unit 110 determines whether to execute the imprint process of the target shot region (determination step). For example, in accordance with the estimation result, the control unit 110 may determine to stop the imprint process for only the target shot region or may determine to stop the imprint process for all the subsequent shot regions including the target shot region. Details of step S102 will be described later. Note that estimation of extrusion of the imprint material IM on the processed shot region can be performed in step S108 to be described later.

In step S103, the control unit 110 supplies/arranges the imprint material IM on the target shot region of the substrate S by the dispenser 108 (supply step). For example, the control unit 110 discharges the imprint material IM as a plurality of droplets from the dispenser 108 while driving the substrate S by the substrate driving mechanism 105, thereby supplying/arranging the imprint material IM on the target shot region.

In step S104, the control unit 110 relatively drives the substrate S and the mold M by at least one of the mold driving mechanism 122 and the substrate driving mechanism 105 such that the pattern region MP of the mold M comes into contact with the imprint material IM on the target shot region (contact step). In an example, the control unit 110 drives the mold M by the mold driving mechanism 122 such that the pattern region MP of the mold M comes into contact with the imprint material IM on the target shot region. Also, in step S104, the control unit 110 controls the pressure (cavity pressure) in the pressure control space CS by the deformation mechanism 123 such that the pattern region MP of the mold M is deformed in a convex shape toward the substrate S in accordance with the distance between the substrate S and the mold M. Here, during step S104, the control unit 110 can accumulate (store), as condition information, information representing a pressing force detected by the sensor 152 and/or information representing the value (deforming force) of the cavity pressure controlled by the deformation mechanism 123. In addition, during step S104, the control unit 110 can accumulate (store), as condition information, a spread image obtained by executing image capturing by the image capturing unit 112.

In step S105, the control unit 110 performs alignment between the target shot region of the substrate S and the pattern region MP of the mold M (alignment step). Alignment can be performed while measuring the relative position between an alignment mark on the target shot region of the substrate S and an alignment mark on the mold M by the alignment measuring device 106 such that the relative position falls within the allowable range of a target relative position. In alignment, the substrate S and the mold M are relatively driven by at least one of the mold driving mechanism 122 and the substrate driving mechanism 105. The target relative position between the alignment mark on the target shot region of the substrate S and the alignment mark on the mold M can be decided by a correction value determined from the result of the overlay inspection apparatus 1005 in the past. Here, during step S105, the control unit 110 can accumulate (store), as condition information, information representing at least one of a driving amount and a driving force for relatively driving the substrate S and the mold M. For example, the driving amount can be obtained from the measurement result of the alignment measuring device 106, and the driving force can be obtained from the detection result of the sensor 151. The control unit 110 may accumulate (store), as condition information, data such as the measurement result (alignment measurement value) of the alignment measuring device 106 or an obtained image (alignment image). During step S105, the control unit 110 can also accumulate (store), as condition information, a shearing force (that is, a force acting between the substrate S and the mold M) detected by the sensor 151.

In step S106, the control unit 110 irradiates, by the curing unit 107, the imprint material IM between the target shot region of the substrate S and the pattern region MP of the mold M with energy for curing the imprint material IM (curing step). Accordingly, the imprint material IM is cured, and a cured product of the imprint material IM is formed.

In step S107, the control unit 110 relatively drives the substrate S and the mold M by at least one of the mold driving mechanism 122 and the substrate driving mechanism 105 such that the pattern region MP of the mold M is separated from the cured product of the imprint material IM on the substrate S (mold separation step). In an example, the control unit 110 drives the mold M by the mold driving mechanism 122 such that the cured product of the imprint material IM and the pattern region 1VIP of the mold M are separated. Also, in step S107, the control unit 110 controls the pressure (cavity pressure) in the pressure control space CS by the deformation mechanism 123 such that the pattern region MP of the mold M is deformed in a convex shape toward the substrate S in accordance with the distance between the substrate S and the mold M. Here, during step S107, the control unit 110 can accumulate (store), as condition information, information representing a mold separation force detected by the sensor 152 and/or information representing the value (deforming force) of the cavity pressure controlled by the deformation mechanism 123. In addition, during step S107, the control unit 110 can accumulate (store), as condition information, a spread image obtained by executing image capturing by the image capturing unit 112.

Various kinds of condition information accumulated in steps S104 to S107 can be supplied (transmitted) to the model generation apparatus 1007 to generate a model used to estimate extrusion of the imprint material IM. The model generation apparatus 1007 can use the various kinds of condition information accumulated in steps S104 to S107 as supervisory data used to generate the model. The model generation method of the model generation apparatus 1007 will be described later. The various kinds of condition information accumulated in steps S104 to S107 are stored (held) in the memory of the control unit 110 and used to estimate the extrusion state of the imprint material IM from the processed shot region using the model generated by the model generation apparatus 1007.

In step S108, based on the various kinds of condition information accumulated in steps S104 to S107 for the target shot region, the control unit 110 estimates the extrusion state of the imprint material IM from the target shot region and stores the estimation result (estimation step). To estimate the extrusion state of the imprint material IM from the target shot region, the model (learned model) generated by the model generation apparatus 1007 is used. The extrusion state of the imprint material IM from the target shot region can include the extrusion amount of the imprint material IM from the target shot region and/or the presence/absence of extrusion of the imprint material IM from the target shot region. The extrusion amount of the imprint material IM can be understood as, for example, the distance of extrusion of the imprint material IM from the boundary of the target shot region. Details of estimation of the extrusion state of the imprint material IM will be described later. Note that the target shot region in step S108 has already undergone steps S103 to S107 described above and may therefore be understood as a processed shot region (first shot region).

In step S109, the control unit 110 determines whether the imprint process in steps S102 to S108 is executed for all shot regions of the substrate S. If the imprint process in steps S102 to S108 is executed for all shot regions of the substrate S, the process advances to step S110, and the control unit 110 conveys, by the substrate conveyance mechanism (not shown), the substrate S from the substrate holding unit 102 to a conveyance destination (for example, a relay unit to a post-processing apparatus). On the other hand, if unprocessed shot regions exist on the substrate S, the process returns to step S102. In this case, the imprint process in steps S102 to S108 can be executed for a shot region selected from the unprocessed shot regions as the target shot region.

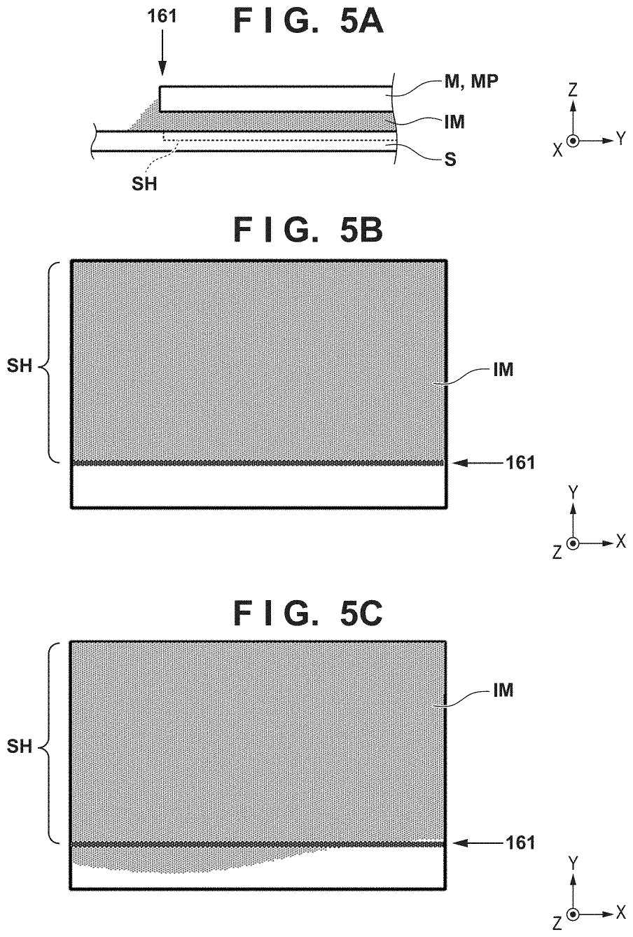

Extrusion of the imprint material IM from the shot region will be described here. FIG. 5A shows a side sectional view of a state in which the mold M and the imprint material IM on the substrate S are in contact (for example, at the end of step S104). Extrusion of the imprint material IM means a state in which the imprint material IM is extruded from a boundary 161 of the shot region SH of the substrate S (or the pattern region MP of the mold M) to the outside of the shot region, as shown in FIG. 5A. FIGS. 5B and 5C are views of a part of the shot region SH (processed shot region) that has undergone the imprint process observed from above (+Z direction) such that the boundary 161 of the shot region SH is included. If the imprint process is normally performed, the imprint material IM spreads and fills up to the boundary 161 of the shot region SH, as shown in FIG. 5B, and the imprint material IM extruded across the boundary 161 to the outside of the shot region SH does not exist. On the other hand, if the amount or supply position of the imprint material IM supplied onto the substrate is inappropriate, the imprint material IM is extruded across the boundary 161 to the outside of the shot region SH, as shown in FIG. 5C. Normally, to prevent extrusion of the imprint material IM from occurring, the amount and supply position of the imprint material IM to be supplied onto the shot region SH are adjusted. However, in the imprint process including physical contact between the mold M and the imprint material IM on the substrate S, extrusion of the imprint material IM may occur due to variations of the operation and state of the imprint apparatus IMP in steps S104 to S106 described above. It is therefore considered that extrusion of the imprint material IM is correlated to the operation and state of the imprint apparatus IMP in steps S104 to S106.

[Determination Step (Step S102)]

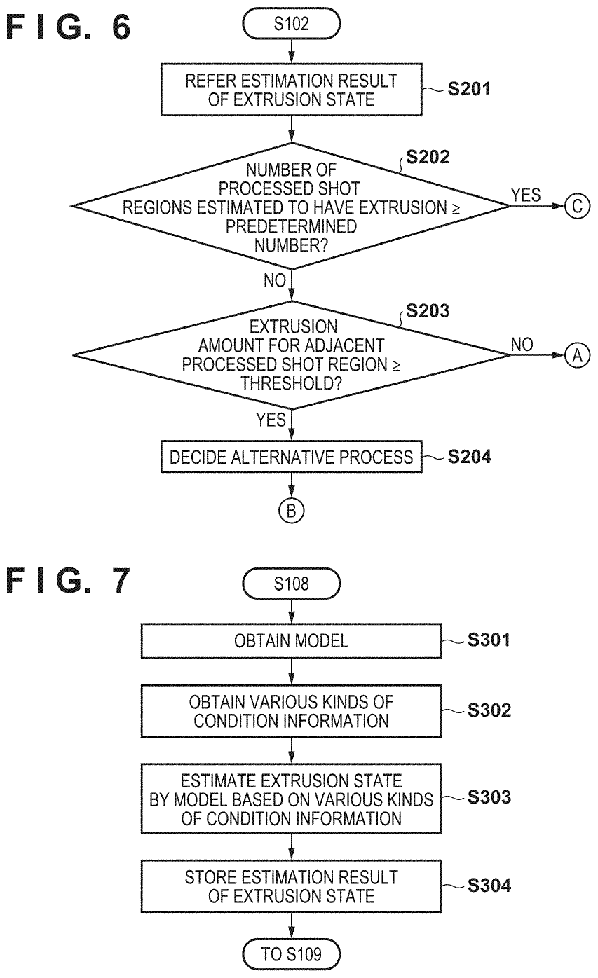

The determination step performed in step S102 will be described next. FIG. 6 is a flowchart showing the determination step performed in step S102. Steps in the flowchart of FIG. 6 can be performed by the control unit 110.

In step S201, the control unit 110 obtains the estimation result of the extrusion state of the imprint material IM on at least one processed shot region of the plurality of shot regions of the substrate S and refers to. The estimation result of the extrusion state of the material IM on each processed shot region is stored in the memory (storage unit) of the control unit 110 by performing step S108 described above. Here, in step S201, for only a processed shot region located adjacent to the target shot region, the control unit 110 may obtain the estimation result of the extrusion state of the imprint material IM and refer to. Alternatively, for all of a plurality of processed shot regions in the substrate S, the control unit 110 may obtain the estimation result of the extrusion state of the imprint material IM and refer to. In this embodiment, an example in which for all of the plurality of processed shot regions, the estimation result of the extrusion state of the imprint material IM is obtained and referred to will be described.

In step S202, the control unit 110 determines, based on the estimation result obtained in step S201, whether the number of processed shot regions estimated to have extrusion of the imprint material IM in the plurality of processed shot regions of the substrate S is a predetermined number or more. The predetermined number is set in advance based on, for example, the past record. If the number of processed shot regions estimated to have extrusion of the imprint material IM is the predetermined number or more, the control unit 110 can determine that the extruded imprint material IM adheres to the mold M. In this case, if the imprint process is executed for the subsequent unprocessed shot region, it may be difficult to accurately form a pattern on the shot region in the imprint process and the mold M may break. Hence, if the number of processed shot regions estimated to have extrusion of the imprint material IM is the predetermined number or more, the control unit 110 determines not to execute the imprint process for the subsequent unprocessed shot regions including the target shot region, and advances to step S110 in FIG. 1. On the other hand, if the number of processed shot regions estimated to have extrusion of the imprint material IM is less than the predetermined number, the process advances to step S203.

In step S203, the control unit 110 determines, based on the estimation result obtained in step S201, whether the extrusion amount of the imprint material IM estimated for the processed shot region located adjacent to the target shot region is equal to or larger than a threshold. The threshold can be set in advance as the extrusion amount of the imprint material IM, with which the imprint material IM extruded from the processed shot region may affect the imprint process of the target shot region. If the extrusion amount of the imprint material is equal to or larger than the threshold, the control unit 110 determines not to execute the imprint process for the target shot region, and advances to step S204. On the other hand, if the extrusion amount of the imprint material is smaller than the threshold, the control unit 110 determines to execute the imprint process for the target shot region, and advances to step S103 in FIG. 1.

In step S204, for the target shot region for which it is determined, in step S203, not to execute the imprint process, the control unit 110 decides an alternative process that replaces the imprint process. The control unit 110 can decide the alternative process for the target shot region in accordance with process contents set in advance. For example, as the alternative process, process contents that “the imprint material is supplied and cured” can be set. The alternative process is processing for preventing the substrate S from being etched, by an etching process as a post-process, in the shot region that has not undergone the imprint process, and can be executed using a mold for the alternative process, which is different from the mold M used in the imprint process. In this case, the control unit 110 supplies the imprint material onto the target shot region, cures the imprint material in a state in which the mold for the alternative process is in contact with the imprint material on the substrate, and separates the mold for the alternative process from the cured imprint material. Such an alternative process is preferably executed after the end of the imprint process of a plurality of substrates S in a lot. Hence, in step S204, the process contents of the alternative process are only decided (determined) in association with the target shot region for which it is determined not to execute the imprint process. Alternatively, as the alternative process, process contents that “nothing is performed” may be set. In this case, the control unit 110 advances the process without performing anything for the target shot region for which it is determined not to execute the imprint process. After the alternative process is decided in step S204, the process advances to step S109 in FIG. 1.

[Estimation Step (Step S108)]

The estimation step performed in step S108 will be described next. FIG. 7 is a flowchart showing the estimation step performed in step S108. Steps in the flowchart of FIG. 7 can be performed by the control unit 110.

In step S301, the control unit 110 obtains a model used to estimate the extrusion state of the imprint material IM from a shot region (obtaining step). The model is a learned model configured to receive various kinds of condition information accumulated in steps S104 to S107 and output the extrusion state of the imprint material IM from a shot region. The control unit 110 may obtain a model stored in the model generation apparatus 1007, or if the model is already stored in the memory (storage unit) of the control unit 110, may obtain (read out) the model from the memory. If the model is stored in the control apparatus 1003, the control unit 110 may obtain the model from the control apparatus 1003.

In step S302, the control unit 110 obtains various kinds of condition information accumulated in steps S104 to S107 for the target shot region. Condition information is information/data representing the state of the imprint apparatus IMP during the imprint process in steps S104 to S107. As described above, the condition information can include information representing the pressing force, the deforming force, and/or the spread image detected during step S104 (contact step). In addition, the condition information can include information representing the driving amount, the driving force, and/or the shearing force detected during step S105 (alignment step). Note that the driving amount and the driving force are values obtained when the substrate S and the mold M are relatively driven in alignment, and are sometimes called stage control values. The condition information may include information representing the alignment measurement value and/or the alignment image obtained during step S105 (alignment step). Furthermore, the condition information can include information representing the mold separation force, the deforming fore, and/or the spread image detected during step S107 (mold separation step).

In step S303, the control unit 110 estimates the extrusion state of the imprint material IM from the target shot region by the model obtained in step S301 based on the various kinds of condition information obtained in step S302. More specifically, when the various kinds of condition information obtained in step S302 are input to the model obtained in step S301, information representing the extrusion state of the imprint material IM from the target shot region is output from the model. Next, in step S304, the control unit 110 stores the estimation result of the extrusion state of the imprint material IM from the target shot region, which is obtained in step S303. Here, as a method of machine learning for generating the model, a method of outputting the reliability of the estimation result in addition to the estimation result of the extrusion state of the imprint material IM from the target shot region can be used. In this case, in step S303, the control unit 110 may estimate the extrusion state of the imprint material IM from the target shot region, calculate (output) the reliability of the estimation result as well, and perform the determination of step S102 in FIG. 1 based on the reliability.

[Model Generation Method]

A method of generating a model for estimating the extrusion state of the imprint material IM from a shot region will be described next. The model generation method to be described below may be included as a model generation step in the obtaining step of step S301 of the flowchart shown in FIG. 7 described above. In this case, model generation can be performed by the control unit 110 of the imprint apparatus IMP.

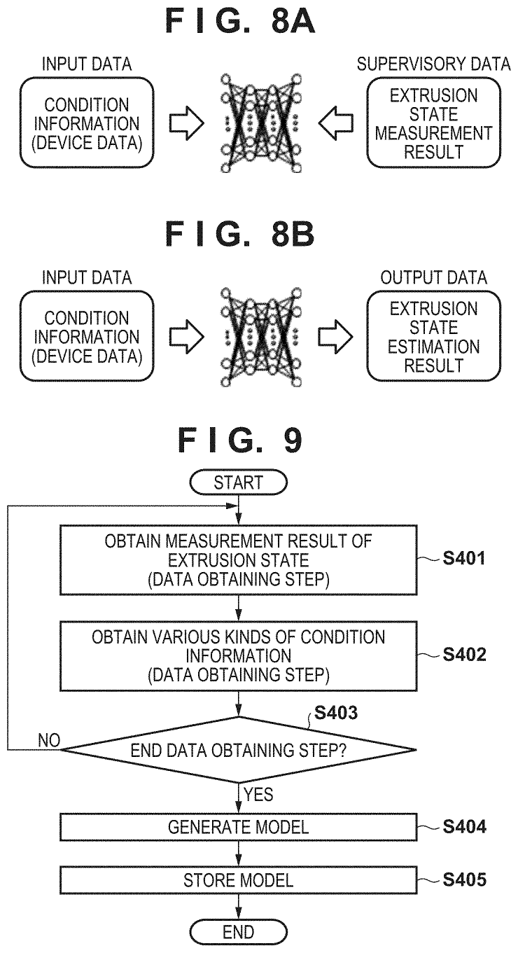

FIGS. 8A and 8B show the outline of a model for estimating the extrusion state of the imprint material IM. In this embodiment, machine learning is used in a process using the model, and a learning step and an estimation step (inference step) are provided. FIG. 8A explains the learning step. Machine learning is performed using, as input data, various kinds of condition information obtained during the imprint process for a plurality of substrates S and, as supervisory data, the measurement result of the extrusion state of the imprint material IM by the imprint process, thereby generating (calculating) the model that is the correlation relationship. The plurality of substrates S used to obtain the condition information as the input data are preferably as many as possible to improve the estimation accuracy by the model. The measurement result of the extrusion state of the imprint material IM is obtained by observing (measuring) the peripheral edge portion of the shot region using the external inspection apparatus 1005 or the like, and can include information representing the presence/absence of extrusion of the imprint material IM from the shot region and/or the extrusion amount. FIG. 8B explains the estimation step. When condition information obtained during the imprint process is input to the model for each shot region, the estimation result of the extrusion state of the imprint material IM can be output from the model.

FIG. 9 is a flowchart showing the method of generating a model for estimating the extrusion state of the imprint material IM. In this embodiment, steps of the model generation method shown in the flowchart of FIG. 9 can be performed by the model generation apparatus 1007. However, the steps may be performed by the control unit 110 of the imprint apparatus IMP, as described above, or may be performed by the control apparatus 1003. That is, the functions of the model generation apparatus 1007 to be described below may be incorporated in the control unit 110 of the imprint apparatus IMP and/or the control apparatus 1003.

Steps S401 and S402 are steps of obtaining, as input data, various kinds of condition information obtained during the imprint process for each of a plurality of shot regions of each of a plurality of substrates S and obtaining the measurement result of the extrusion state of the imprint material IM as supervisory data. Steps S401 and S402 will sometimes be referred to as a data obtaining step hereinafter.

In step S401, the model generation apparatus 1007 obtains, from the external inspection apparatus 1005, the measurement result of the extrusion state of the imprint material IM for a shot region of interest. The measurement result of the extrusion state of the imprint material IM can include the measurement result of the presence/absence of extrusion of the imprint material IM from the shot region of interest and/or the measurement result of the extrusion amount of the imprint material IM from the shot region of interest.

In step S402, the model generation apparatus 1007 obtains, from the imprint apparatus IMP, various kinds of condition information obtained during the imprint process for the shot region of interest. The various kinds of condition information can be stored in association with the measurement result of the extrusion state of the imprint material IM obtained in step S401. The various kinds of condition information obtained in step S402 are the information/data described concerning step S302 described above, and preferably match the various kinds of condition information obtained in step S302.

In step S403, the model generation apparatus 1007 determines whether to end the data obtaining step of steps S401 and S402. For example, it may be determined to end the data obtaining step if the measurement result of the extrusion state of the imprint material IM and various kinds of condition information are obtained for all shot regions of the plurality of substrates S that have undergone the imprint process under predetermined conditions. Alternatively, it may be determined to end the data obtaining step if the measurement result of the extrusion state of the imprint material IM and various kinds of condition information are obtained for several sample shot regions of the plurality of substrates S. Furthermore, it may be determined to end the data obtaining step if the measurement result of the extrusion state of the imprint material IM and various kinds of condition information, which are necessary for accurately generating the model, are obtained. If it is determined not to end the data obtaining step yet, the process returns to step S401. If it is determined to end the data obtaining step, the process advances to step S404.

In step S404, the model generation apparatus 1007 performs machine learning of the correlation relationship between the measurement result of the extrusion state of the imprint material IM and various kinds of condition information, which are obtained in the data obtaining step, thereby generating the model for estimating the extrusion state of the imprint material IM. As the means of machine learning, a method can be used in which a neural network formed by multiple layers of perceptrons is prepared, and an internal random variable is optimized such that the extrusion state of the imprint material IM is reproduced based on the condition information obtained from the imprint apparatus IMP. If image information such as an alignment image or a spread image is used as condition information, a convolutional neural network is suitable as the means of machine learning. If condition information is information such as a stage control value that changes along with the elapse of time, a recursive neural network is suitable as the means of machine learning. In this embodiment, a neural network is used as the means of machine learning. If the amount of measurement result is small, a support vector machine may be used in place of the neural network. By performing such machine learning, the model (learned model) used to estimate the extrusion state of the imprint material TM based on the various kinds of condition information can be generated.

In step S405, the model generation apparatus 1007 stores (saves) the model generated in step S404. Here, the model generated in the above-described way may successively be updated. For example, since the condition information and the measurement result of the extrusion state of the imprint material IM are obtained in each imprint process, the model may be updated for each imprint process. Also, if a predetermined period elapses, or the imprint process is performed a predetermined number of times, the model may be updated.

As described above, the imprint apparatus IMP according to this embodiment estimates the extrusion state of the imprint material IM from the processed shot region using the model configured to receive condition information representing the condition of the imprint process and output the extrusion state of the imprint material IM. Then, based on the extrusion state of the imprint material IM estimated for the processed shot region, it is determined whether to execute the imprint process for a target shot region scheduled to undergo the imprint process. Since it is unnecessary to capture each of a plurality of partial regions of a shot region by a camera of a high magnification (high resolution) and analyze, it can be advantageous in terms of apparatus cost and throughput.

### Embodiment of Method of Manufacturing Article

A method of manufacturing an article according to the embodiment of the present invention is suitable for manufacturing an article, for example, a microdevice such as a semiconductor device or an element having a microstructure. The method of manufacturing an article according to the embodiment includes a step of forming a pattern to an imprint material supplied (applied) onto a substrate by using the above-described imprint apparatus (imprint method) and a step of processing the substrate on which the pattern has been formed in the preceding step. Furthermore, this manufacturing method includes other well-known steps (for example, oxidization, deposition, vapor deposition, doping, planarization, etching, resist removal, dicing, bonding, and packaging, and the like). The method of manufacturing an article according to the embodiment is superior to a conventional method in at least one of the performance, quality, productivity, and production cost of the article.

The pattern of a cured material formed using the imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile or nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured material is directly used as the constituent member of at least some of the above-described articles or used temporarily as a resist mask. After etching or ion implantation is performed in the substrate processing step, the resist mask is removed.

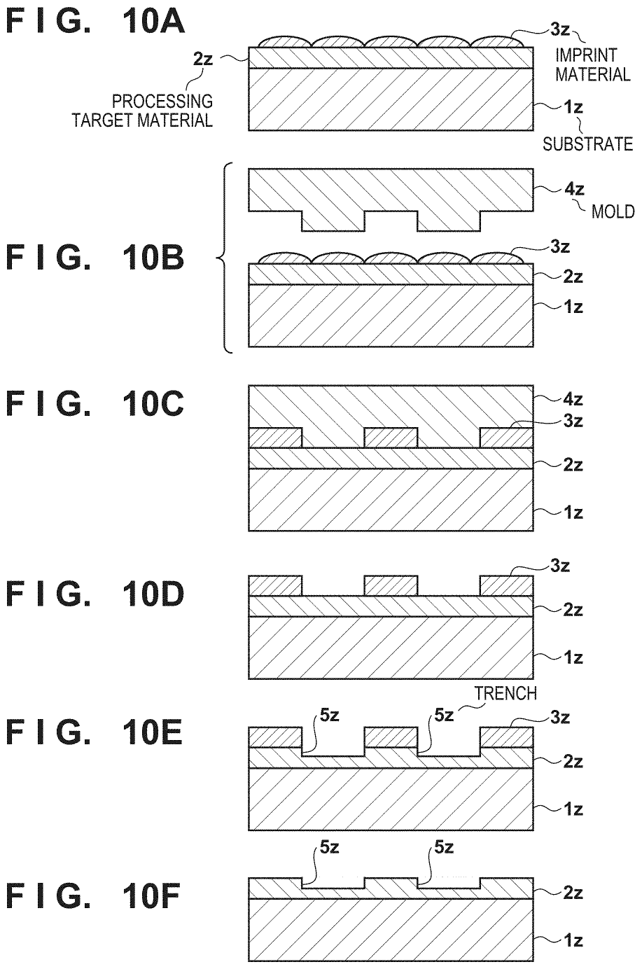

A detailed method of manufacturing an article will be described next. As shown in FIG. 10A, a substrate 1z such as a silicon wafer with a target material 2z to be processed such as an insulator formed on the surface is prepared. Next, an imprint material 3z is applied to the surface of the target material 2z by an inkjet method or the like. A state in which the imprint material 3z is applied as a plurality of droplets onto the substrate is shown here.

As shown in FIG. 10B, a mold 4z for imprint is caused to face to the substrate 1z such that a pattern with convex and concave portions formed in the mold 4z is directed to the imprint material 3z on the substrate 1z. As shown in FIG. 10C, the mold 4z and the imprint material 3z applied on the substrate 1z are brought into contact with each other, and subjected to a pressure. The gap between the mold 4z and the target material 2z is filled with the imprint material 3z. In this state, by irradiating the imprint material 3z with energy for curing through the mold 4z, the imprint material 3z is cured.

As shown in FIG. 10D, after the imprint material 3z is cured, the mold 4z is separated from the substrate 1z. Then, the pattern of the cured material of the imprint material 3z is formed on the substrate 1z. In the pattern of the cured material, the concave portion of the mold corresponds to the convex portion of the cured material, and the convex portion of the mold corresponds to the concave portion of the cured material. That is, the pattern with convex and concave portions in the mold 4z is transferred to the imprint material 3z.

As shown in FIG. 10E, by performing etching process using the pattern of the cured material as an etching resistant mask, a portion of the surface of the target material 2z where the cured material does not exist or remains thin is removed to form a groove 5z. As shown in FIG. 10F, by removing the pattern of the cured material, an article with the grooves 5z formed in the surface of the target material 2z can be obtained. Here, the pattern of the cured material is removed. However, instead of processing or removing the pattern of the cured material, it may be used as, for example, an interlayer dielectric film included in a semiconductor element or the like, that is, a constituent member of an article.

### Other Embodiments

Embodiment(s) of the present invention can also be realized by a computer of a system or apparatus that reads out and executes computer executable instructions (e.g., one or more programs) recorded on a storage medium (which may also be referred to more fully as ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-136653 filed on Aug. 24, 2021, which is hereby incorporated by reference herein in its entirety.

What is claimed is:

1. An imprint method of performing, for each of a plurality of shot regions on a substrate, a process of forming a pattern of an imprint material on the substrate using a mold, comprising:
obtaining a model configured to receive condition information representing a condition of the process and output an extrusion state of the imprint material from a shot region;
estimating the extrusion state of the imprint material from at least one first shot region that has already undergone the process among the plurality of shot regions, by the model, based on the condition information obtained in the process of the first shot region; and
determining, based on the extrusion state in the first shot region estimated in the estimating, whether to execute the process for a second shot region scheduled to undergo the process next to the first shot region among the plurality of shot regions.

2. The method according to claim 1, wherein
in the estimating, an extrusion amount of the imprint material from the first shot region is estimated by the model as the extrusion state, and
in the determining, whether to execute the process for the second shot region is determined in accordance with the extrusion amount estimated in the estimating.

3. The method according to claim 2, wherein the second shot region is a shot region adjacent to the first shot region among the plurality of shot regions.

4. The method according to claim 1, wherein
in the estimating, presence/absence of extrusion of the imprint material is estimated by the model as the extrusion state for each of a plurality of first shot regions that have already undergone the process, and
in the determining, whether to execute the process for the second shot region is determined, in accordance with the number of first shot regions estimated to have the extrusion of the imprint material in the estimating.

5. The method according to claim 1, wherein
the process includes bringing the mold and the imprint material on the substrate into contact with each other in a state in which the mold is deformed in a convex shape toward the substrate, and
the condition information includes information representing a pressing force for pressing the mold against the imprint material on the substrate to bring the mold and the imprint material on the substrate into contact with each other.

6. The method according to claim 5, wherein the condition information includes information representing a deforming force applied to the mold to deform the mold in the convex shape.

7. The method according to claim 1, wherein
the process includes performing an alignment between the mold and the substrate in a state in which the mold and the imprint material on the substrate are in contact with each other, and
the condition information includes information representing at least one of a driving amount and a driving force for relatively driving the mold and the substrate in the alignment.

8. The method according to claim 7, wherein the condition information includes information representing a shearing force that acts between the mold and the substrate in the alignment.

9. The method according to claim 1, wherein
the process includes separating the mold from the cured imprint material on the substrate, and
the condition information includes information representing a mold separation force for separating the mold from the cured imprint material on the substrate in the separating.

10. The method according to claim 1, wherein the condition information includes an image obtained by capturing a shot region under the process.

11. The method according to claim 1, wherein the obtaining includes generating the model by performing machine learning using the condition information as input data and a measurement result of the extrusion state as supervisory data.

12. A method of manufacturing an article, the method comprising:
forming a pattern on a substrate by using an imprint method according to claim 1;
processing the substrate, on which the pattern has been formed, to manufacture the article.

13. A non-transitory computer-readable storage medium storing a program for causing a computer to execute an imprint method according to claim 1.

14. An imprint apparatus for performing, for each of a plurality of shot regions on a substrate, a process of forming a pattern of an imprint material on the substrate using a mold, wherein the imprint apparatus is configured to:
obtain a model configured to receive condition information representing a condition of the process and output an extrusion state of the imprint material from a shot region;
estimate the extrusion state of the imprint material from at least one first shot region that has already undergone the process among the plurality of shot regions, by the model, based on the condition information obtained in the process of the first shot region; and
determine, based on the estimated extrusion state in the first shot region, whether to execute the process for a second shot region scheduled to undergo the process next to the first shot region among the plurality of shot regions.

15. A model configured to receive condition information representing a condition of a process of forming a pattern of an imprint material on a shot region on a substrate using a mold, and output an extrusion state of the imprint material from the shot region.

16. A method of generating a model configured to receive condition information representing a condition of a process of forming a pattern of an imprint material on a shot region on a substrate using a mold, and output an extrusion state of the imprint material from the shot region, comprising;
generating the model by performing machine learning using the condition information as input data and a measurement result of the extrusion state as supervisory data.

17. A non-transitory computer-readable storage medium storing a program for causing a computer to execute a generation method according to claim 16.
